(19) United States
(12) Patent Application Publication
(10) Pub. No.: US 2025/0237717 A1
(43) Pub. Date: Jul. 24, 2025

(54) MAGNETIC FIELD SENSOR WITH BIAS RESISTOR

(71) Applicant: TEXAS INSTRUMENTS INCORPORATED, Dallas, TX (US)

(72) Inventors: Keith Ryan Green, McKinney, TX (US); Charles Parkhurst, Lucas, TX (US)

(21) Appl. No.: 18/679,729

(22) Filed: May 31, 2024

Related U.S. Application Data
(60) Provisional application No. 63/624,105, filed on Jan. 23, 2024.

(51) Int. Cl. G01R 33/07; H10N 52/00; H10N 52/01

(52) U.S. Cl. CPC G01R 33/07; H10N 52/01; H10N 52/101

(57) ABSTRACT

The present disclosure generally relates to a magnetic field sensor in an integrated circuit (IC). In an example, an IC includes a magnetic field sensor and a resistor. The magnetic field sensor includes a first doped well and a second doped well. The first doped well and the second doped well are in a semiconductor substrate. A first spacing is between the first doped well and the second doped well. The resistor includes a third doped well in the semiconductor substrate. A second spacing is between the first doped well and the third doped well. The second spacing is equal to the first spacing.

### CROSS-REFERENCE TO RELATED APPLICATIONS

This application claims priority to and the benefit of U.S. Provisional Patent Application Ser. No. 63/624,105, filed on Jan. 23, 2024, which is incorporated herein by reference in its entirety.

### BACKGROUND

Various types of sensors have been developed to detect the presence of a magnetic field. A Hall sensor is one type of sensor that may be used to detect the presence, and measure the magnitude, of a magnetic field. The output voltage of a Hall sensor may be proportional to the magnetic field strength through the Hall sensor. Hall sensors may be used for proximity sensing, positioning, speed detection, and current sensing applications.

### SUMMARY

This summary is provided to introduce a brief selection of disclosed concepts in a simplified form that are further described below in the detailed description including the drawings provided. Various disclosed devices and methods may be beneficially applied in the context of an integrated circuit (IC) including a magnetic field sensor (e.g., a Hall sensor) with a bias resistor. Some examples described herein may be applied in such ICs and to manufacturing such ICs. While such examples may be expected to achieve, among other things, improved drift compensation of a Hall sensor, no particular result is a requirement unless explicitly recited in a particular claim.

An example described herein is an IC. The IC includes a magnetic field sensor and a resistor. The magnetic field sensor includes a first doped well and a second doped well. The first doped well and the second doped well are in a semiconductor substrate. A first spacing is between the first doped well and the second doped well. The resistor includes a third doped well in the semiconductor substrate. A second spacing is between the first doped well and the third doped well. The second spacing is equal to the first spacing.

Another example described herein is an IC. The IC includes a sensor cell on a semiconductor substrate. The sensor cell includes a magnetic field sensor and a resistor. The magnetic field sensor includes a sensor doped well in the semiconductor substrate. The resistor includes a resistor doped well in the semiconductor substrate.

A further example described herein is a method of manufacturing an IC. A first doped well, a second doped well, and a third doped well are formed in a semiconductor substrate. A first spacing is between the first doped well and the second doped well. A second spacing is between the first doped well and the third doped well. The second spacing is equal to the first spacing. The first doped well and the second doped well are electrically connected in a magnetic field sensor in the IC. The third doped well is electrically connected in a resistor in the IC.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features may be understood in detail, reference is made to the following detailed description taken in conjunction with the accompanying drawings.

FIG. 1 is an integrated circuit including a Hall sensor and a bias resistor according to some examples.

FIG. 2 is a layout view of a sensor cell including a Hall sensor and a bias resistor according to some examples.

FIGS. 3A and 3B are respective the cross-sectional views of the sensor cell of FIG. 2 according to some examples.

FIG. 4 is a flowchart of a method for fabricating an integrated circuit according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and may be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to an integrated circuit (IC) that includes a magnetic field sensor (e.g., a Hall sensor) and a bias resistor. In some examples, an IC includes a sensor cell on a semiconductor substrate. The sensor cell includes a magnetic field sensor and a resistor. The magnetic field sensor includes one or more sensor doped wells in the semiconductor substrate, and the resistor includes one or more dummy/resistor doped wells in the semiconductor substrate. In some examples, the dummy/resistor doped well(s) may be electrically connected as the bias resistor in the IC. Various examples may achieve improved drift compensation for the magnetic field sensor and reduced area consumption on the semiconductor die of the IC. Other benefits or advantages may be achieved by various examples.

Examples described herein implement a Hall sensor as an example magnetic field sensor. The Hall sensor in these examples includes sensor doped wells in a semiconductor substrate, where the sensor doped wells are electrically connected (e.g., through metal contacts, metal vias, and metal lines) to detect a magnetic field by the Hall effect. The examples illustrated in the figures show a vertical or in-plane Hall sensor. Additionally, the examples illustrated in the figures show a single direction vertical or in-plane Hall sensor. Other examples may implement a horizontal or out-of-plane Hall sensor and/or a multiple directional Hall sensor (e.g., two directional vertical or in-plane or other). Further, the Hall sensor depicted in the figures includes four sensor doped wells (e.g., a quad). In other examples, a Hall sensor may include any number of sensor doped wells (e.g., one, two, four, eight, etc.). Other magnetic field sensors may also be implemented in an IC.

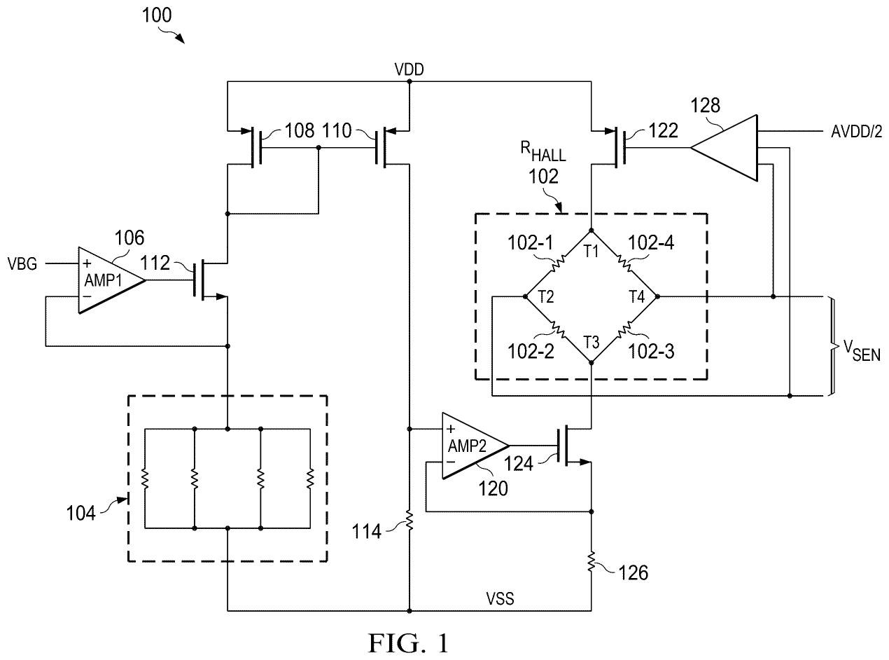

FIG. 1 is an IC 100 including a Hall sensor 102 and a bias resistor 104 according to some examples. The IC 100 is on a single die or chip. The components of the IC 100 may be fabricated on and/or in a semiconductor substrate. The IC 100 is an example IC in which a sensor cell comprising sensor doped wells of the Hall sensor 102 and dummy/resistor doped wells for forming the bias resistor 104 may be implemented. Other ICs including such a sensor cell may be implemented in other examples.

The IC 100 includes a first operational amplifier (op amp) 106, a first transistor 108, a second transistor 110, a third transistor 112, and a first resistor 114. The first transistor 108 and second transistor 110, in the illustrated example, are respective p-type transistors, such as p-type field effect transistors (pFETs) (e.g., p-type metal-oxide-semiconductor (pMOS) FETs). The third transistor 112, in the illustrated example, is an n-type transistor, such an n-type field effect transistor (nFET) (e.g., an n-type metal-oxide-semiconductor (nMOS) FET).

The first transistor 108 and second transistor 110 are electrically connected in a current mirror configuration. The respective source nodes of the first transistor 108 and second transistor 110 are electrically connected to a positive power supply node (VDD), and the respective gate nodes of the first transistor 108 and second transistor 110 are electrically connected together, to a drain node of the first transistor 108, and to a drain node of the third transistor 112. The gate node of the third transistor 112 is electrically connected to an output node of the first op amp 106. A backgate voltage node (VBG) is electrically connected to a positive input node of the first op amp 106. The source node of the third transistor 112 is electrically connected to a negative input node of the first op amp 106. The negative input node of the first op amp 106 and the source node of the third transistor 112 are further electrically connected to a first node of the bias resistor 104. A second node of the bias resistor 104 (opposite from the first node) is or is electrically connected to a negative power supply node (VSS). The bias resistor 104, as illustrated, includes multiple resistors connected in parallel between the first node and the second node. The resistors may be formed in respective doped wells in the semiconductor substrate, as detailed subsequently. In other examples, the bias resistor 104 may be a single resistor between the first node and the second node or may include multiple resistors connected in series or in any network of series and/or parallel configuration. The drain node of the second transistor 110 is electrically connected to a first terminal of the first resistor 114, and a second terminal of the first resistor 114 is or is electrically connected to the negative power supply node (VSS).

The IC 100 further includes a second op amp 120, a fourth transistor 122, a fifth transistor 124, a second resistor 126, and a third op amp 128. The fourth transistor 122, in the illustrated example, is a p-type transistor, such as a pFET (e.g., a pMOS FET). The fifth transistor 124, in the illustrated example, is an n-type transistor, such an nFET (e.g., an nMOS FET).

The source node of the fourth transistor 122 is electrically connected to the positive power supply node (VDD), and a drain node of the fourth transistor 122 is electrically connected to a first node (T1) of the Hall sensor 102. A third node (T3) of the Hall sensor 102 is electrically connected to a drain node of the fifth transistor 124. The source node of the fifth transistor 124 is electrically connected to a negative input node of the second op amp 120. The negative input node of the second op amp 120 and the source node of the fifth transistor 124 are further electrically connected to a first terminal of the second resistor 126. A second terminal of the second resistor 126 is or is electrically connected to the negative power supply node (VSS). A positive input node of the second op amp 120 is electrically connected to the drain node of the second transistor 110 and the first terminal of the first resistor 114.

The Hall sensor 102 includes resistances electrically connected together in a Wheatstone bridge configuration, which has a differential node (T2, T4) pair between which a sensor voltage (VSEN) may be detected. A resistance 102-1 is electrically between the first node (T1) and the second node (T2); a resistance 102-2 is electrically between the second node (T2) and the third node (T3); a resistance 102-3 is electrically between the third node (T3) and the fourth node (T4); and a resistance 102-4 is electrically between the fourth node (T4) and the first node (T1). The differential node (T2, T4) pair is electrically connected to a differential input node pair of the third op amp 128. An input node of the third op amp 128 is electrically connected to a half analog positive power supply node (AVDD/2). An output node of the third op amp 128 is electrically connected to the gate node of the fourth transistor 122. The third op amp 128 is configured to set a common mode voltage at the differential node (T2, T4) pair of the Hall sensor 102. The third op amp 128 senses the differential voltage between the differential node (T2, T4) pair of the Hall sensor 102 and forces a voltage at the gate node of the fourth transistor 122 that will establish a current that translates into AVDD/2 by means of the resistance of the Hall sensor 102.

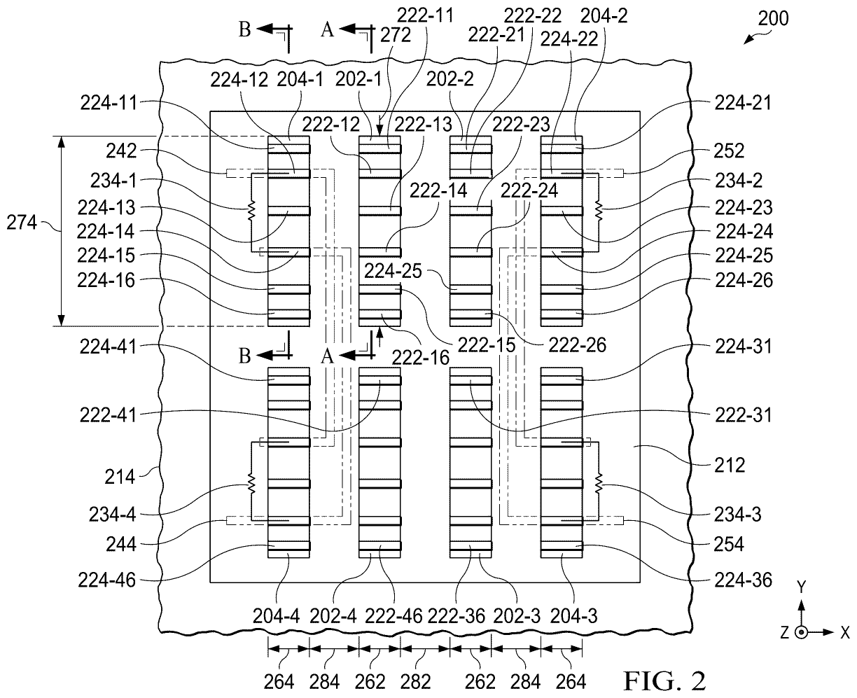

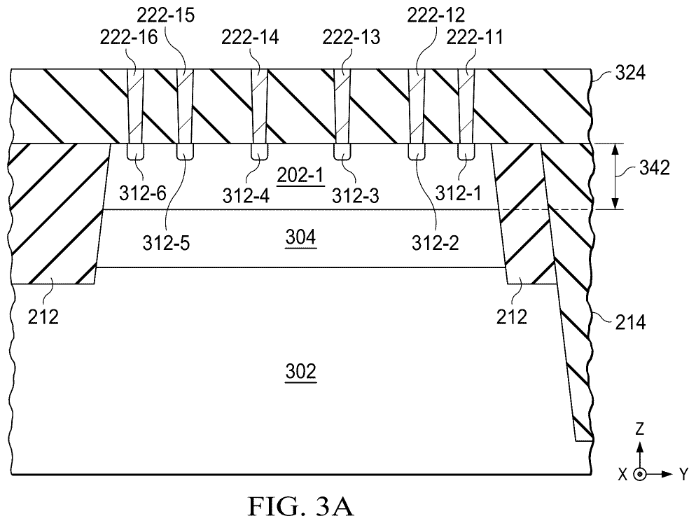

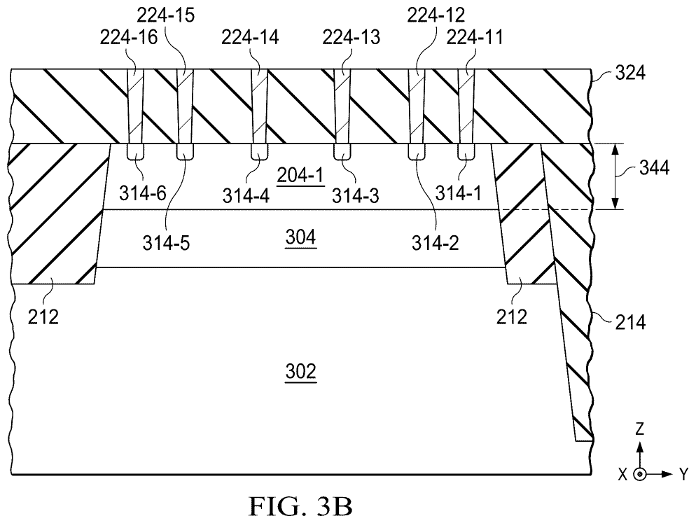

FIG. 2 is a layout view of a sensor cell 200 including a Hall sensor and a bias resistor according to some examples. The layout is shown in an x-y plane. The layout of the sensor cell 200 of FIG. 2 shows a cross-section A-A and a cross-section B-B. The cross-sections A-A, B-B are in z-y planes. FIG. 3A illustrates the cross-section A-A, and FIG. 3B illustrates the cross-section B-B. The following description may be understood with reference to FIGS. 2, 3A, and 3B.

The sensor cell 200 includes sensor doped wells 202-1, 202-2, 202-3, 202-4 (collectively or individually, sensor doped well(s) 202) and dummy or resistor (hereinafter, “dummy/resistor”) doped wells 204-1, 204-2, 204-3, 204-4 (collectively or individually, dummy/resistor doped well(s) 204). Four sensor doped wells 202 and four dummy/resistor doped wells 204 are illustrated. In other examples, other numbers of sensor doped wells and dummy/resistor doped wells may be implemented, such as one sensor doped well, two sensor doped wells, eight sensor doped wells, etc. and corresponding dummy/resistor doped wells. The cross-section A-A is through the sensor doped well 202-1. Although FIG. 3A illustrates the sensor doped well 202-1, FIG. 3A may be representative of any sensor doped well 202. Similarly, the cross-section B-B is through the dummy/resistor doped well 204-1. Although FIG. 3B illustrates the dummy/resistor doped well 204-1, FIG. 3B may be representative of any dummy/resistor doped well 204.

A shallow isolation structure 212, e.g. a shallow trench isolation (STI) structure, is between and laterally defines the sensor doped wells 202 and dummy/resistor doped wells 204. A deep isolation structure 214 laterally encircles or encompasses the sensor doped wells 202, dummy/resistor doped wells 204, and shallow isolation structure 212.

The sensor doped wells 202 and dummy/resistor doped wells 204 have respective longitudinal axes (axes along a major axis of the structure) that are parallel to each other (e.g., in respective y-directions). The sensor doped wells 202-1, 202-4 are longitudinally aligned (e.g., in a y-direction), and the sensor doped wells 202-2, 202-3 are longitudinally aligned (e.g., in a y-direction). The dummy/resistor doped wells 204-1, 204-4 are longitudinally aligned (e.g., in a y-direction), and the dummy/resistor doped wells 204-2, 204-3 are longitudinally aligned (e.g., in a y-direction). The sensor doped wells 202-1, 202-2 are laterally between (e.g., in an x-direction) the dummy/resistor doped wells 204-1, 204-2, e.g., such that midpoints of the respective longitudinal axes of the sensor doped wells 202-1, 202-2 and the dummy/resistor doped wells 204-1, 204-2 align (e.g., in an x-direction). The sensor doped wells 202-3, 202-4 are laterally between (e.g., in an x-direction) the dummy/resistor doped wells 204-3, 204-4, e.g., such that midpoints of the respective longitudinal axes of the sensor doped wells 202-3, 202-4 and the dummy/resistor doped wells 204-3, 204-4 align (e.g., in an x-direction).

Respective spacings between a dummy/resistor doped well 204 and a neighboring sensor doped well 202 (or dummy/resistor doped well 204) may be equal to a spacing between neighboring sensor doped wells 202 along a same direction. As illustrated, neighboring sensor doped wells 202 (e.g., sensor doped wells 202-1, 202-2 or sensor doped wells 202-3, 202-4) along an x-direction have a spacing 282 therebetween. Each dummy/resistor doped well 204 has a spacing 284 along an x-direction to a neighboring sensor doped well 202. More specifically, a respective spacing 284 is between the dummy/resistor doped well 204-1 and the sensor doped well 202-1, between the dummy/resistor doped well 204-2 and the sensor doped well 202-2, between the dummy/resistor doped well 204-3 and the sensor doped well 202-3, and between the dummy/resistor doped well 204-4 and the sensor doped well 202-4. The spacings 282, 284 may be, and are illustrated as, equal. Similarly, along y-directions, a respective spacing between neighboring sensor doped wells 202 (e.g., between sensor doped wells 202-1, 202-4) may be, and is illustrated as, equal to a respective spacing between neighboring dummy/resistor doped wells 204 (e.g., between dummy/resistor doped wells 204-1, 204-4). In some examples, the spacing 284 between a dummy/resistor doped well 204 and a neighboring sensor doped well 202 is equal to or less than 10 μm, such as in a range from 4 μm to 10 μm.

FIGS. 3A and 3B show a semiconductor substrate 302. The semiconductor substrate 302 may be or include a bulk semiconductor substrate, a semiconductor-on-insulator (SOI) substrate, or other semiconductor substrate, and in some cases, may include one or more epitaxial layer epitaxially grown on an underlying substrate. In some examples, the semiconductor substrate 302 is or includes a bulk silicon substrate (e.g., singulated from a wafer), which may further include one or more silicon epitaxial layers epitaxially grown on the bulk silicon substrate.

The shallow isolation structure 212 extends into the semiconductor substrate 302 and laterally bounds the sensor doped well 202-1 and the dummy/resistor doped well 204-1. The shallow isolation structure 212 extends from an upper surface of the semiconductor substrate 302 to a depth in the semiconductor substrate 302. The shallow isolation structure 212 may be or include silicon oxide or another dielectric material. In some examples, the shallow isolation structure 212 is a shallow trench isolation (STI), and in other examples, the shallow isolation structure 212 may be another isolation region, such as a field oxide (FOX) and/or local oxidation of silicon (LOCOS) structure.

The deep isolation structure 214 extends into the semiconductor substrate 302 and laterally encircles or encompasses the sensor doped wells 202, the dummy/resistor doped well 204, and shallow isolation structure 212 (as illustrated in FIG. 2). The deep isolation structure 214 extends from the upper surface of the semiconductor substrate 302 to a depth in the semiconductor substrate 302 that is greater than the depth in the semiconductor substrate 302 to which the shallow isolation structure 212 extends. The deep isolation structure 214 may be or include silicon oxide, another dielectric material, a dielectric liner with a fill material (that may or may not be a dielectric material), or another isolation structure. In some examples, the deep isolation structure 214 is a deep trench isolation (DTI) structure.

A doped buried layer 304 is in the semiconductor substrate 302, and the sensor doped well 202-1 and the dummy/resistor doped well 204-1 are over the doped buried layer 304. In FIG. 3A, the doped buried layer 304 and the sensor doped well 202-1 are laterally between portions of the shallow isolation structure 212. In FIG. 3B, the doped buried layer 304 and the dummy/resistor doped well 204-1 are laterally between portions of the shallow isolation structure 212. The doped buried layer 304, the sensor doped wells 202, and the dummy/resistor doped wells 204 may be doped by a same conductivity type dopant. In some examples, the doped buried layer 304, the sensor doped wells 202, and the dummy/resistor doped wells 204 are doped with n-type dopants. In such examples, the doped buried layer 304 may be an n-doped buried layer (NBL), and the sensor doped wells 202 and the dummy/resistor doped wells 204 may n-doped wells (NWells). As used herein, a buried layer (BL) is a layer in a semiconductor substrate and with characteristics, such as conductivity type or dopant concentration, that is spaced apart from a top surface of the semiconductor substrate by a spacing layer or material that has a significantly different characteristics, such as different conductivity type or different dopant concentration. For example a BL may be an n-doped diffusion layer spaced apart from the top surface of the substrate by an n-type or p-type in-situ doped epitaxial layer. In some examples, the doped buried layer 304 may be omitted. In some examples, another doped buried layer may be between the doped buried layer 304 and each sensor doped well 202 and between the doped buried layer 304 and each dummy/resistor doped well 204 and may be doped an opposite conductivity type (e.g., a p-type dopant) from the doped buried layer 304, the sensor doped wells 202, and the dummy/resistor doped wells 204.

Referring to FIG. 3A, doped contact regions 312-1, 312-2, 312-3, 312-4, 312-5, 312-6 (collectively or individually, doped contact region(s) 312) are in the sensor doped well 202-1 in the semiconductor substrate 302. The doped contact regions 312 extend from the upper surface of the semiconductor substrate 302 to a depth in the semiconductor substrate 302 and in the sensor doped well 202-1. In the illustrated example, the sensor doped well 202-1 includes six doped contact regions 312. In other examples, other numbers of doped contact regions 312 may be included in a sensor doped well 202. The doped contact regions 312 may be doped by a same conductivity type dopant as the sensor doped well 202-1 and the doped buried layer 304. For example, the doped contact regions 312, the sensor doped well 202-1, and the doped buried layer 304 each may be n-type doped. The doped contact regions 312 may be doped to a concentration that is greater than the dopant concentration of the sensor doped well 202-1, and the dopant concentration of the sensor doped well 202-1 may be less than the dopant concentration of the doped buried layer 304.

Referring to FIG. 3B, doped contact regions 314-1, 314-2, 314-3, 314-4, 314-5, 314-6 (collectively or individually, doped contact region(s) 314) are in the dummy/resistor doped well 204-1 in the semiconductor substrate 302. The doped contact regions 314 extend from the upper surface of the semiconductor substrate 302 to a depth in the semiconductor substrate 302 and in the dummy/resistor doped well 204-1. In the illustrated example, the dummy/resistor doped well 204-1 includes six doped contact regions 314. In other examples, other numbers of doped contact regions 314 may be included in a dummy/resistor doped well 204. The doped contact regions 314 may be doped by a same conductivity type dopant as the dummy/resistor doped well 204-1 and the doped buried layer 304. For example, the doped contact regions 314, the dummy/resistor doped well 204-1, and the doped buried layer 304 each may be n-type doped. The doped contact regions 314 may be doped to a concentration that is greater than the dopant concentration of the dummy/resistor doped well 204-1, and the dopant concentration of the dummy/resistor doped well 204-1 may be less than the dopant concentration of the doped buried layer 304.

In some examples, an n-dopant concentration of each doped contact regions 312, 314 may be in a range from 1×10¹⁹ cm⁻³ to 1×10²¹ cm⁻³. In some examples, an n-dopant concentration of each sensor doped well 202 and each dummy/resistor doped well 204 may be in a range from 1×1016 cm⁻³ to 1×10¹⁸ cm⁻³. In some examples, an n-dopant concentration of the doped buried layer 304 may be in a range from 1×10¹⁸ cm⁻³ to 1×10²⁰ cm⁻³. Other dopant concentrations may be implemented.

Referring to FIGS. 3A and 3B, an interconnect structure is on or over the semiconductor substrate 302. The interconnect structure, as illustrated, includes a dielectric layer 324. The dielectric layer 324 may include a pre-metal dielectric (PMD) layer, one or more etch stop layers (ESLs), the like, or a combination thereof. Each dielectric layer 324 may be or include silicon oxide, borophosphosilicate glass (BPSG), phosphosilicate glass (PSG), silicon nitride, silicon oxynitride, silicon oxycarbon nitride, silicon oxycarbide, or the like.

In FIG. 3A, metal contacts 222-11, 222-12, 222-13, 222-14, 222-15, 222-16 (collectively or individually, metal contact(s) 222) are through the dielectric layer 324 and contact a respective doped contact region 312-1, 312-2, 312-3, 312-4, 312-5, 312-6. In FIG. 3B, metal contacts 224-11, 224-12, 224-13, 224-14, 224-15, 224-16 (collectively or individually, metal contact(s) 224) are through the dielectric layer 324 and contact a respective doped contact region 314-1, 314-2, 314-3, 314-4, 314-5, 314-6. As shown in FIG. 2, each sensor doped well 202-m has metal contacts 222-m1, 222-m2, 222-m3, 222-m4, 222-m5, 222-m6 (with respective doped contact region 312), and each dummy/resistor doped well 204-n has metal contacts 224-n1, 224-n2, 224-n3, 224-n4, 224-n5, 224-n6 (with respective doped contact region 314). The metal contacts 222, 224 may include (i) one or more barrier and/or adhesion layers (e.g., titanium nitride (TiN), tantalum nitride (TaN), the like, or a combination thereof) conformally in a respective opening through the dielectric layer 324 and (ii) a fill metal (e.g., tungsten (W), copper (Cu), aluminum (Al), the like, or a combination thereof) on the one or more barrier and/or adhesion layers.

Although not illustrated, the interconnect structure may include additional dielectric layers, such as inter-metal dielectric (IMD) layers, ESLs, the like, or a combination thereof, over the dielectric layer 324. The additional dielectric layers may each be or include silicon oxide, BPSG, PSG, silicon nitride, silicon oxynitride, silicon oxycarbon nitride, silicon oxycarbide, or the like. Further, metal lines and metal vias may be on and/or in the dielectric layers to interconnect various components. The metal vias and metal lines may include one or more barrier and/or adhesion layers (e.g., titanium nitride (TiN), tantalum nitride (TaN), the like, or a combination thereof) and a fill metal (e.g., tungsten (W), copper (Cu), aluminum (Al), the like, or a combination thereof) on the one or more barrier and/or adhesion layer.

As an example of electrical connections in the interconnect structure to form a Hall sensor, the metal contacts 222-12, 222-23, 222-34, 222-45 may be electrically connected together as a first node (T1); the metal contacts 222-22, 222-33, 222-44, 222-15 may be electrically connected together as a second node (T2); the metal contacts 222-32, 222-43, 222-14, 222-25 may be electrically connected together as a third node (T3); and the metal contacts 222-42, 222-13, 222-24, 222-35 may be electrically connected together as a fourth node (T4). The portions of the sensor doped wells 202 between the metal contacts 222 that form the first node (T1) and the metal contacts 222 that form the second node (T2) form the resistance 102-1 in FIG. 1. The portions of the sensor doped wells 202 between the metal contacts 222 that form the second node (T2) and the metal contacts 222 that form the third node (T3) form the resistance 102-2 in FIG. 1. The portions of the sensor doped wells 202 between the metal contacts 222 that form the third node (T3) and the metal contacts 222 that form the fourth node (T4) form the resistance 102-3 in FIG. 1. The portions of the sensor doped wells 202 between the metal contacts 222 that form the fourth node (T4) and the metal contacts 222 that form the first node (T1) form the resistance 102-4 in FIG. 1.

The metal contacts 224 may be electrically connected together to form the bias resistor 104 of FIG. 1. The bias resistor 104 is formed by the resistance through the dummy/resistor doped well(s) 204 that are electrically connected to form the bias resistor 104. As an example, the sensor cell 200 of FIG. 2 includes metal lines 242, 244, 252, 254. The metal lines 242 (with metal vias (not illustrated)) electrically connect the metal contacts 224-12, 224-43. The metal lines 244 (with metal vias (not illustrated)) electrically connect the metal contacts 224-14, 224-45. Hence, the resistance of the dummy/resistor doped well 204-1 between the metal contacts 224-12, 224-14 (illustrated by resistor 234-1) and the resistance of the dummy/resistor doped well 204-4 between the metal contacts 224-43, 224-45 (illustrated by resistor 234-4) are electrically connected in parallel. The metal lines 252 (with metal vias (not illustrated)) electrically connect the metal contacts 224-22, 224-33. The metal lines 254 (with metal vias (not illustrated)) electrically connect the metal contacts 224-24, 224-35. Hence, the resistance of the dummy/resistor doped well 204-2 between the metal contacts 224-22, 224-24 (illustrated by resistor 234-2) and the resistance of the dummy/resistor doped well 204-3 between the metal contacts 224-33, 224-35 (illustrated by resistor 234-3) are electrically connected in parallel. Further, the metal lines 242, 252 may be electrically connected together, such as through other metal layers, and the metal lines 244, 254 may be electrically connected together, which may electrically connect the resistances (illustrated by resistors 234-1, 234-2, 234-3, 234-4) in parallel.

In other examples, different metal contacts 224 may be electrically connected to form any network of resistances of the dummy/resistor doped wells 204. In some examples, some of the dummy/resistor doped wells 204 are not electrically connected as part of the bias resistor 104 and may simply be a dummy doped well. In such examples in which any dummy/resistor doped well 204 is not electrically connected by additional metal layers to another component (e.g., such as another dummy/resistor doped well 204), that dummy/resistor doped well 204 may be electrically isolated from each other dummy/resistor doped well 204 and each sensor doped well 202.

The dummy/resistor doped wells 204 individually may have the same characteristics, within process variation, as the sensor doped wells 202 individually. The dummy/resistor doped wells 204 may each have the same lateral width, lateral length, depth, and doping profile as the sensor doped wells 202. As illustrated in FIG. 2, the sensor doped wells 202 each have a lateral width 262, and the dummy/resistor doped wells 204 each have a lateral width 264. The lateral widths 262, 264 are equal in the illustrate example. The sensor doped wells 202 each have a lateral length 272, and the dummy/resistor doped wells 204 each have a lateral length 274. The lateral lengths 272, 274 are equal in the illustrate example. As illustrated in FIGS. 3A and 3B, the sensor doped wells 202 each are formed to a depth 342 in the semiconductor substrate 302 from the upper surface of the semiconductor substrate 302, and the dummy/resistor doped wells 204 are formed to a depth 344 in the semiconductor substrate 302 from the upper surface of the semiconductor substrate 302. The depths 342, 344 are equal in the illustrate example. The sensor doped wells 202 and the dummy/resistor doped wells 204 may be doped using a same process, and hence, have a same dopant (and more generally, same dopant type) and a same dopant concentration profile, which may be any combination of uniform concentration and/or gradient concentration.

The presence of the dummy/resistor doped wells 204 may reduce the variability of residual offset of the Hall sensor formed with the sensor doped wells 202. For example, in some instances, the presence of the dummy/resistor doped wells 204 have been found to reduce the standard deviation of residual offset by 20% relative to a Hall sensor having sensor doped wells without proximate dummy doped wells.

Using dummy/resistor doped wells 204 within the sensor cell 200 as the bias resistor 104 in the IC 100 may provide drift compensation for the Hall sensor 102 formed using the sensor cell 200. By being in a same sensor cell 200, the dummy/resistor doped wells 204 are within close proximity to the sensor doped wells 202 that are used to form the Hall sensor 102. With the dummy/resistor doped wells 204 forming the bias resistor 104, the dummy/resistor doped wells 204 may provide compensation for process, voltage, and/or temperature (PVT) variation and strain variation. Strain may be induced by a package, by temperature expansion (e.g., differing coefficients of thermal expansions (CTEs) of different materials), humidity, etc.). The dummy/resistor doped wells 204 may provide this compensation because the dummy/resistor doped wells 204 are formed by the same process(es) as the sensor doped wells 202 and the dummy/resistor doped wells 204 likely experience the same environmental and processing factors as the sensor doped wells 202 due to the close proximity. The dummy/resistor doped wells 204 and sensor doped wells 202 may also have matched piezo coefficients. Additionally, the dummy/resistor doped wells 204 may continue to reduce the standard deviation of residual offset of the Hall sensor even when implemented as a bias resistor. Further, implementing the bias resistor in the dummy/resistor doped wells 204 may reduce the area consumed on a die or chip for the bias resistor.

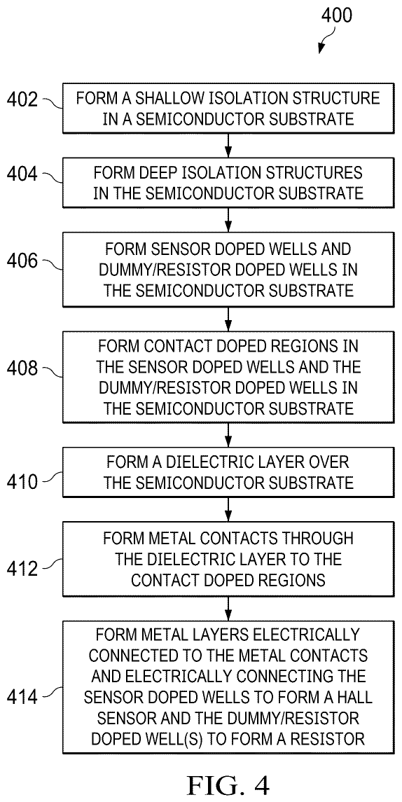

FIG. 4 is a flowchart of a method 400 for fabricating an integrated circuit according to some examples. The integrated circuit includes a Hall sensor and a bias resistor as described above.

At block 402, a shallow isolation structure 212 is formed in a semiconductor substrate 302. At block 404, a deep isolation structure 214 is formed in the semiconductor substrate 302. At block 406, sensor doped wells 202 and dummy/resistor doped wells 204 are formed in the semiconductor substrate 302. Blocks 402-406 may be performed in various orders and using various techniques.

For example, the shallow isolation structure 212 may be formed in the semiconductor substrate 302 (e.g., a bulk semiconductor substrate) by etching shallow trenches and filling the shallow trenches with a dielectric material or with a dielectric liner and another fill material over the dielectric liner. Then, the deep isolation structure 214 may be formed in the semiconductor substrate 302 by etching deep trenches and filling the deep trenches with a dielectric material or with a dielectric liner and another fill material over the dielectric liner. Then, the sensor doped wells 202 and dummy/resistor doped wells 204 may be formed by implanting dopants into the semiconductor substrate 302, where the shallow isolation structure 212 defines the lateral boundaries of the sensor doped wells 202 and dummy/resistor doped wells 204.

As another example, the semiconductor substrate 302 includes an epitaxial semiconductor layer over a support substrate. The epitaxial semiconductor layer may be in-situ doped with dopants during the epitaxial growth, which forms the dopant profiles of the sensor doped wells 202 and dummy/resistor doped wells 204. Then, the shallow isolation structure 212 may be formed in the semiconductor substrate 302 by etching shallow trenches and filling the shallow trenches with a dielectric material or with a dielectric liner and another fill material over the dielectric liner. The shallow isolation structure 212 defines the lateral boundaries of the sensor doped wells 202 and dummy/resistor doped wells 204. Then, the deep isolation structure 214 may be formed in the semiconductor substrate 302 by etching deep trenches and filling the deep trenches with a dielectric material or with a dielectric liner and another fill material over the dielectric liner.

At block 408, doped contact regions 312, 314 are formed in the sensor doped wells 202 and the dummy/resistor doped wells 204 in the semiconductor substrate 302. The doped contact regions 312, 314 may be formed by implanting dopants. At block 410, a dielectric layer 324 is formed over the semiconductor substrate 302. The dielectric layer 324 may be formed using any appropriate deposition process. At block 412, metal contacts 222, 224 are formed through the dielectric layer 324 to respective doped contact regions 312, 314. The metal contacts 222, 224 may be formed by forming openings through the dielectric layer 324 to the doped contact regions 312, 314, such as by appropriate photolithography and etching processes, and depositing metal in the opening using appropriate deposition processes. Excess metal may be removed by patterning the metal, such as by appropriate photolithography and etching processes, or by a planarization process, such as a chemical mechanical polish (CMP). At block 414, metal layers are formed electrically connected to the metal contacts 222, 224 and electrically connecting the sensor doped wells 202 to form a Hall sensor and one or more of the dummy/resistor doped wells 204 to form a resistor, where the resistor is a bias resistor in the integrated circuit. The metal layers may be formed in an interconnect structure using appropriate processes in back-end-of-the-line (BEOL) processing.

Although various examples have been described in detail, it should be understood that various changes, substitutions, and alterations may be made therein without departing from the scope defined by the appended claims.

What is claimed is:

1. An integrated circuit (IC) comprising:
a magnetic field sensor comprising a first doped well and a second doped well, the first doped well and the second doped well being in a semiconductor substrate, a first spacing being between the first doped well and the second doped well; and
a resistor comprising a third doped well in the semiconductor substrate, a second spacing being between the first doped well and the third doped well, the second spacing being equal to the first spacing.

2. The IC of claim 1, further comprising:
a first isolation structure in the semiconductor substrate and between the first doped well, the second doped well, and the third doped well; and
a second isolation structure in the semiconductor substrate and encompassing the first doped well, the second doped well, and the third doped well, and the first isolation structure, the second isolation structure extending to a depth in the semiconductor substrate that is greater than a depth to which the first isolation structure extends.

3. The IC of claim 1, wherein:
the first doped well has a first lateral width and a first lateral length and extends to a first depth in the semiconductor substrate;
the third doped well has a second lateral width and a second lateral length and extends to a second depth in the semiconductor substrate;
the first lateral width is equal to the second lateral width;
the first lateral length is equal to the second lateral length; and
the first depth is equal to the second depth.

4. The IC of claim 1, wherein:
the first doped well has a first doping profile;
the third doped well has a second doping profile; and
the first doping profile is the same as the second doping profile.

5. The IC of claim 1, wherein the first doped well, the second doped well, and the third doped well are longitudinally parallel to each other.

6. The IC of claim 1, further comprising a fourth doped well in the semiconductor substrate, a third spacing being between the fourth doped well and the second doped well, the third spacing being equal to the first spacing.

7. The IC of claim 6, wherein:
the magnetic field sensor comprises a fifth doped well and a sixth doped well, the fifth doped well and the sixth doped well being in the semiconductor substrate; and
the resistor comprises a seventh doped well in the semiconductor substrate;
the first doped well, the second doped well, the third doped well, and the fourth doped well being longitudinally parallel to each other;
the fifth doped well, the sixth doped well, and the seventh doped well being longitudinally parallel to each other;
the first doped well and the fifth doped well being longitudinally aligned;
the second doped well and the sixth doped well being longitudinally aligned; and
the third doped well and the seventh doped well being longitudinally aligned.

8. The IC of claim 1, wherein the resistor further comprises a fourth doped well in the semiconductor substrate, a third spacing being between the fourth doped well and the second doped well, the third spacing being equal to the first spacing.

9. The IC of claim 8, wherein:
the magnetic field sensor comprises a fifth doped well and a sixth doped well, the fifth doped well and the sixth doped well being in the semiconductor substrate; and
the resistor comprises a seventh doped well and an eighth doped well, the seventh doped well and the eighth doped well being in the semiconductor substrate;
the first doped well, the second doped well, the third doped well, and the fourth doped well being longitudinally parallel to each other;
the fifth doped well, the sixth doped well, the seventh doped well, and the eighth doped well being longitudinally parallel to each other;
the first doped well and the fifth doped well being longitudinally aligned;
the second doped well and the sixth doped well being longitudinally aligned;
the third doped well and the seventh doped well being longitudinally aligned; and
the fourth doped well and the eighth doped well being longitudinally aligned.

10. An integrated circuit (IC) comprising:
a sensor cell on a semiconductor substrate, the sensor cell comprising:
a magnetic field sensor comprising a first sensor doped well in the semiconductor substrate; and
a resistor comprising a first resistor doped well in the semiconductor substrate.

11. The IC of claim 10, wherein the first sensor doped well and the first resistor doped well have a same doping profile.

12. The IC of claim 10, wherein:
the first sensor doped well has a first lateral length and a first lateral width, the first sensor doped well extending to a first depth in the semiconductor substrate;
the first resistor doped well has a second lateral length and a second lateral width, the first resistor doped well extending to a second depth in the semiconductor substrate;
the first lateral length and the second lateral length being parallel and equal to each other;
the first lateral width and the second lateral width being equal to each other; and
the first depth and the second depth being equal to each other.

13. The IC of claim 10, wherein the sensor cell includes a deep trench isolation, the deep trench isolation being along a periphery of the sensor cell.

14. The IC of claim 10, wherein:
the magnetic field sensor comprises a second sensor doped well in the semiconductor substrate;
the first sensor doped well, the second sensor doped well, and the first resistor doped well are longitudinally parallel to each other; and
a spacing between the first sensor doped well and the second sensor doped well is equal to a spacing between the first sensor doped well and the first resistor doped well.

15. The IC of claim 10, wherein the sensor cell comprises a dummy doped well in the semiconductor substrate, the dummy doped well being electrically isolated from the first sensor doped well and the first resistor doped well.

16. The IC of claim 10, wherein:
the magnetic field sensor comprises a second sensor doped well in the semiconductor substrate;
the resistor comprises a second resistor doped well in the semiconductor substrate;
the first sensor doped well, the second sensor doped well, the first resistor doped well, and the second resistor doped well being longitudinally parallel to each other; and
the first sensor doped well and the second sensor doped well being laterally between the first resistor doped well and the second resistor doped well.

17. The IC of claim 10, wherein:
the magnetic field sensor comprises a second sensor doped well in the semiconductor substrate;
the resistor comprises a second resistor doped well in the semiconductor substrate;
the first sensor doped well and the first resistor doped well being longitudinally parallel to each other;
the second sensor doped well and the second resistor doped well being longitudinally parallel to each other;
the first sensor doped well and the second sensor doped well being longitudinally aligned; and
the first resistor doped well and the second resistor doped well being longitudinally aligned.

18. The IC of claim 10, wherein:
the magnetic field sensor comprises a second sensor doped well, a third sensor doped well, and a fourth sensor doped well in the semiconductor substrate;
the resistor comprises a second resistor doped well in the semiconductor substrate;
the first sensor doped well, the second sensor doped well, the third sensor doped well, the fourth sensor doped well, the first resistor doped well, and the second resistor doped well are longitudinally parallel to each other;
the first sensor doped well and the third sensor doped well being longitudinally aligned; and
the second sensor doped well and the fourth sensor doped well being longitudinally aligned.

19. A method of manufacturing an integrated circuit (IC), the method comprising:
forming a first doped well, a second doped well, and a third doped well in a semiconductor substrate, a first spacing being between the first doped well and the second doped well, a second spacing being between the first doped well and the third doped well, the second spacing being equal to the first spacing;
electrically connecting the first doped well and the second doped well in a magnetic field sensor in the IC; and
electrically connecting the third doped well in a resistor in the IC.

20. The method of claim 19, wherein:
the first doped well, the second doped well, and the third doped well have respective same lateral lengths;
the first doped well, the second doped well, and the third doped well have respective same lateral widths;
the first doped well, the second doped well, and the third doped well extend respective same depths into the semiconductor substrate; and
the first doped well, the second doped well, and the third doped well have respective same doping profiles.
